(19) United States
(12) Patent Application Publication
(10) Pub. No.: US 2026/0206539 A1
(43) Pub. Date: Jul. 16, 2026

(54) TREATING AN ELECTROSTATIC CHUCK PEDESTAL

(71) Applicant: Lam Research Corporation, Fremont, CA (US)

(72) Inventors: Mahmoud VAHIDI, Lake Oswego, OR (US); Sergey Georgiyevich BELOSTOTSKIY, Sherwood, OR (US); Joel HOLLINGSWORTH, Portland, OR (US); Karl Frederick LEESER, West Linn, OR (US); Ahmet KUCUK, Sunnyvale, CA (US)

(21) Appl. No.: 19/137,024

(22) PCT Filed: Dec. 13, 2023
(86) PCT No.: PCT/US2023/083885

§ 371 Date: Jun. 9, 2025

Related U.S. Application Data
(60) Provisional application No. 63/476,237, filed on Dec. 20, 2022.

(51) Int. Cl. H10P 72/72; B23K 26/12; B23K 26/352; B23K 103/00; C01B 21/072

(52) U.S. Cl. CPC H10P 72/722; B23K 26/1224; B23K 26/125; B23K 26/126; B23K 26/352; C01B 21/0728; B23K 2103/52

(57) ABSTRACT

A method for laser treating an electrostatic chuck pedestal comprises selectively applying a laser beam to a substrate contact area of the electrostatic chuck pedestal to form a microstructurally modified layer on at least a portion of the substrate contact area.

### BACKGROUND

Electrostatic chuck pedestals are used in many semiconductor manufacturing processes to hold substrates such as silicon wafers. A substrate-facing surface of the electrostatic chuck pedestal may be patterned with substrate contact areas that form contact points between the electrostatic chuck pedestal and the substrate.

### SUMMARY

This Summary is provided to introduce a selection of concepts in a simplified form that are further described below in the Detailed Description. This Summary is not intended to identify key features or essential features of the claimed subject matter, nor is it intended to be used to limit the scope of the claimed subject matter. Furthermore, the claimed subject matter is not limited to implementations that solve any or all disadvantages noted in any part of this disclosure.

Examples are disclosed that relate to laser treating an electrostatic chuck pedestal. In one example method, a laser beam is selectively applied to a substrate contact area of the electrostatic chuck pedestal to form a microstructurally modified layer on at least a portion of the substrate contact area.

In some such examples, selectively applying the laser beam to the substrate contact area additionally or alternatively comprises selectively applying the laser beam in a presence of oxygen, and the microstructurally modified layer additionally or alternatively includes an oxide layer.

In some such examples, the oxide layer additionally or alternatively comprises one or more of aluminum oxide or aluminum oxynitride.

In some such examples, the method additionally or alternatively comprises selectively applying the laser beam to at least a portion of a substrate-facing surface of the electrostatic chuck pedestal outside of the substrate contact area.

In some such examples, the electrostatic chuck pedestal additionally or alternatively comprises aluminum nitride.

In some such examples, the method additionally or alternatively comprises selectively applying the laser beam to the substrate contact area in the presence of a dopant to thereby incorporate the dopant into the microstructurally modified layer.

In some such examples, the method additionally or alternatively comprises providing the dopant as a gas that forms at least a portion of an atmosphere in which the laser beam is applied to the substrate contact area.

In some such examples, the method additionally or alternatively comprises providing the dopant as a solid or a liquid on the substrate contact area.

In some such examples, the dopant additionally or alternatively comprises one or more of carbon, magnesium, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, lutetium, or silicon.

In some such examples, the method additionally or alternatively comprises selectively applying the laser beam to the substrate contact area in a nitrogen-enriched atmosphere.

In some such examples, the electrostatic chuck pedestal additionally or alternatively comprises a degraded electrostatic chuck pedestal.

In some such examples, the oxide layer additionally or alternatively comprises a thickness of greater than or equal to 100 nm.

Another example provides a method. The method comprises selectively applying a laser beam to at least a portion of a substrate-facing surface of an electrostatic chuck pedestal outside of one or more substrate contact areas of the substrate-facing surface of the electrostatic chuck pedestal to thereby form a microstructurally modified layer on at least the portion of the substrate-facing surface.

In some such examples, selectively applying the laser beam to at least the portion of the substrate-facing surface additionally or alternatively comprises selectively applying the laser beam in a presence of oxygen, and the microstructurally modified layer additionally or alternatively includes an oxide layer.

In some such examples, the method additionally or alternatively comprises selectively applying the laser beam to at least a portion of a substrate contact area of the one or more substrate contact areas.

In some such examples, the method additionally or alternatively comprises selectively applying the laser beam in the presence of a dopant to thereby incorporate the dopant into the microstructurally modified layer.

In some such examples, the electrostatic chuck pedestal additionally or alternatively comprises aluminum nitride.

In some such examples, the microstructurally modified layer additionally or alternatively comprises a thickness of greater than or equal to 100 nm.

Another example provides an electrostatic chuck pedestal. The electrostatic chuck pedestal comprises a substrate-facing surface comprising a substrate contact area. The electrostatic chuck pedestal also comprises a microstructurally modified layer on at least a portion of the substrate contact area. The microstructurally modified layer comprises a thickness of greater than or equal to 100 nm.

In some such examples, the microstructurally modified layer additionally or alternatively comprises an oxide layer.

### BRIEF DESCRIPTION OF THE DRAWINGS

FIG. 1A schematically illustrates laser treating an example electrostatic chuck pedestal to form an example microstructurally modified layer on one or more substrate contact areas (SCAs) of the electrostatic chuck pedestal.

FIG. 1B illustrates the oxide layer formed on the one or more SCAs of the electrostatic chuck pedestal of FIG. 1A.

FIG. 1C illustrates a substrate positioned on the electrostatic chuck pedestal of FIG. 1B.

FIG. 2 shows a top-down schematic view of the example electrostatic chuck pedestal of FIGS. 1A-C.

FIG. 3 shows a schematic side profile view of another example electrostatic chuck pedestal comprising an oxide layer on a plurality of SCAs and on other regions of a substrate-facing surface.

FIG. 4 schematically illustrates laser treating an example electrostatic chuck pedestal in the presence of a gas comprising a dopant precursor.

FIG. 5 schematically illustrates an example of laser treating an electrostatic chuck pedestal using a solid or liquid dopant precursor.

FIG. 6A shows a plot illustrating a surface relief profile for an example degraded electrostatic chuck pedestal.

FIG. 6B shows a plot illustrating a surface relief profile for an example refurbished electrostatic chuck pedestal.

FIG. 7 shows a flow diagram depicting an example method for laser treating an electrostatic chuck pedestal.

FIG. 8 shows a flow diagram depicting another example method for laser treating an electrostatic chuck pedestal.

FIG. 9 schematically shows an example computing system.

### DETAILED DESCRIPTION

The term “abrading” generally represents mechanically removing material from an electrostatic chuck pedestal during fabrication. Examples of abrading include blasting the electrostatic chuck pedestal with an abrasive material. The term “blasting” generally represents propelling the abrasive material with sufficient speed to cause mechanical removal of material from the electrostatic chuck pedestal.

The term “atmosphere” generally represents a gaseous environment in which an electrostatic chuck pedestal is located during application of a laser beam.

The term “dopant” generally represents a substance incorporated into an electrostatic chuck pedestal that modifies one or more physical or chemical properties of the electrostatic chuck pedestal. Example dopants for an oxide layer of an electrostatic chuck pedestal include silicon, carbon, magnesium, aluminum, molybdenum, tungsten, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, and lutetium.

The term “electrostatic chuck pedestal” generally represents a substrate holder configured to securely hold a semiconductor substrate during a process by generation of an electrostatic force.

The term “laser beam” generally represents a beam of coherent electromagnetic radiation output from a laser.

The term “microstructurally modified layer” generally represents a layer of material that comprises a different microstructure than at least a portion of a material adjacent to the microstructurally modified layer. A microstructurally modified layer may have a different crystal structure, a different morphology, a different chemical composition, a different grain size, and/or any other suitable difference compared to an unmodified material.

The term “nitrogen-enriched atmosphere” generally represents an atmosphere that contains a greater concentration of nitrogen than a concentration of nitrogen in air.

The term “oxide layer” generally represents a layer of an electrostatic chuck pedestal comprising an oxide formed by exposure to a laser under an oxygen-containing atmosphere. Example oxides in an oxide layer include aluminum oxynitride ((AlN)ₓ·(Al₂O₃)₁₋ₓ,) and aluminum oxide (Al₂O₃).

The term “selectively applying a laser beam” generally represents applying a laser beam to a targeted area of a surface.

The term “substrate contact area” generally represents a portion of an electrostatic chuck pedestal that is configured to make physical contact with a substrate when the substrate is placed on the electrostatic chuck pedestal.

The term “substrate-facing surface” generally represents a portion of an electrostatic chuck pedestal that faces towards a substrate when the substrate is placed on the electrostatic chuck pedestal.

The term “laser treating” generally represents subjecting an electrostatic chuck pedestal to laser energy to modify a material composition of the electrostatic chuck pedestal.

The term “degraded electrostatic chuck pedestal” generally represents an electrostatic chuck pedestal comprising a surface that has become damaged or worn from use compared to an unused electrostatic chuck pedestal.

In many semiconductor processes, an electrostatic chuck pedestal is used to hold a semiconductor substrate during the process. Some electrostatic chuck pedestals are known as Johnsen-Rahbek (J-R) chucks. Such electrostatic chuck pedestals have substrate contact area (SCA) features each comprising a dielectric layer with a finite resistance. An electric current conducted through the dielectric layer and the substrate creates a charge layer at the dielectric-substrate interface. This charge layer creates an attractive electrostatic force to clamp the substrate to the electrostatic chuck pedestal. The dielectric layer may comprise a ceramic material, such as aluminum nitride (AlN).

The SCAs of a J-R electrostatic chuck pedestal are patterned on a substrate-facing surface of the electrostatic chuck pedestal. The SCAs serve as contact points between the electrostatic chuck pedestal and the substrate for current flow between the electrostatic chuck and the substrate.

Electrostatic chuck pedestals may be used in a variety of semiconductor processes. Examples include film deposition processes such as chemical vapor deposition (CVD) and atomic layer deposition (ALD). Prior to performing a film deposition process, a protective film may be deposited on an electrostatic chuck pedestal and other surfaces within a processing chamber. The protective film is removed after the deposition process has been performed on a batch of substrates. The protective film may be removed using a plasma cleaning process in which a plasma generates fluorine-containing radical species from a cleaning species precursor. An example cleaning species precursor for generating fluorine radicals is nitrogen trifluoride (NF₃). However, the plasma cleaning process can damage the SCAs of the electrostatic chuck pedestal. For example, grains of the ceramic material of the SCAs may be dislodged or chemically degraded during a cleaning process. This can result in the formation of voids on the SCAs. Over time, such grain removal results in pedestal wear.

Electric current that flows through the electrostatic chuck pedestal during use also may degrade the SCAs of the electrostatic chuck pedestal over time. Such degradation may arise from ionic currents within the ceramic material of the electrostatic chuck.

SCAs of an electrostatic chuck pedestal potentially may be refurbished, such as by machining or melting and reflowing the SCAs, to decrease the depth of voids. Further, surrounding areas of a substrate-facing surface also may be machined to maintain a selected SCA feature height. However, the machining removes material from the electrostatic chuck pedestal. As such, the refurbishment may be performed, if at all, only a small number of times for an electrostatic chuck pedestal before too much material has been removed. Replacement of an electrostatic chuck pedestal can be expensive and result in processing tool down time.

Accordingly, examples are disclosed that relate to laser treating an electrostatic chuck pedestal in a manner that may help to resist such wear. The disclosed examples also may be used to refurbish a degraded electrostatic chuck pedestal. Briefly, a laser beam is selectively applied to a SCA of the electrostatic chuck pedestal. The selective application of the laser beam forms a microstructurally modified layer on at least a portion of the SCA. The laser beam may additionally or alternatively be applied to at least a portion of a substrate-facing surface of the electrostatic chuck pedestal outside of the SCA. The laser treatment results in formation of the microstructurally modified layer on at least the portion of the substrate-facing surface outside of the SCA. In some examples, the laser beam is selectively applied in a presence of oxygen. In this manner, the microstructurally modified layer may comprise an oxide layer. The oxide layer can alter electrical properties of the electrostatic chuck pedestal. As such, the oxide layer can alter the clamping performance of the electrostatic chuck pedestal. The laser exposure also may render the substrate-facing surface and/or the SCA more resistant to wear than an untreated electrostatic chuck pedestal. For example, a laser-modified layer on a substrate-facing surface of the electrostatic chuck pedestal can be engineered to have a different hardness than the electrostatic chuck pedestal. This can prevent substrate backside defects, such as scratching and contamination by electrostatic chuck pedestal materials. Further, the electrostatic chuck pedestal may be refurbished one or more using the laser beam without significantly reducing its thickness compared to machining. This may extend a lifetime of the electrostatic chuck pedestal through multiple use and refurbishment cycles. In other examples, other microstructural modifications may be made. For example, one or more dopants can be added to the pedestal by use of a laser beam treatment in the presence of the one or more dopants. Also, morphological changes can be made by treatment of a laser beam.

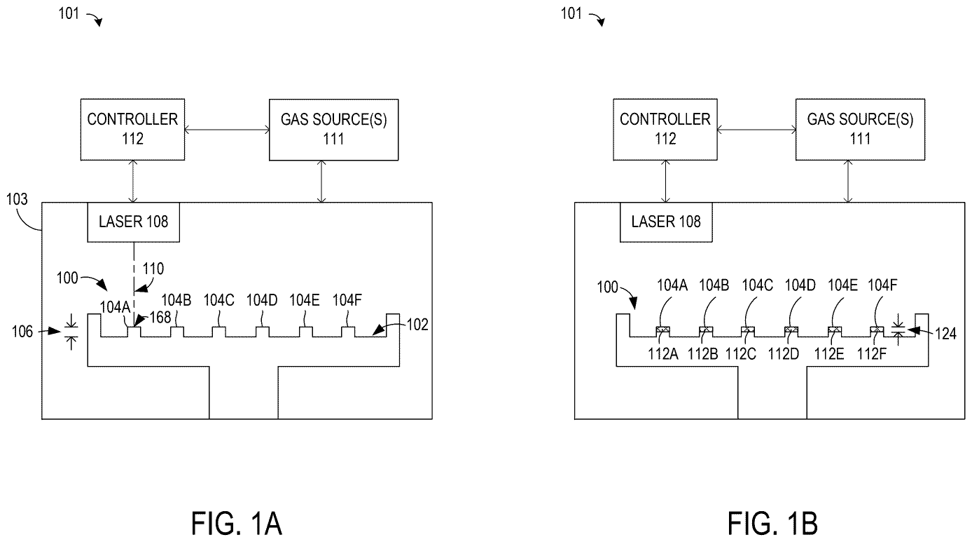

FIGS. 1A-1C schematically show an example tool 101 for laser treating an electrostatic chuck pedestal 100. The tool 101 comprises a chamber 103 configured to house the electrostatic chuck pedestal 100 during the laser treatment. The electrostatic chuck pedestal 100 comprises a dielectric material with some electrical conductivity to hold a wafer using the above-described J-R mechanism. The dielectric material may comprise AlN in some examples. Further, the tool 101 may comprise a computer numerical control (CNC) laser machine in some examples.

The electrostatic chuck pedestal 100 comprises a substrate-facing surface 102. The substrate-facing surface 102 comprises SCAs 104A-104F configured to contact the substrate during the operation of the electrostatic chuck pedestal 100. In this schematic, each of the SCAs 104A-104F comprises a cylindrical shape. In other examples, the SCAs 104A-104F may have any other suitable shape(s). Other examples of suitable shapes include, but are not limited to, hemispheroids, cuboids, and other polygonal shapes.

In some examples, the SCAs 104A-104F are formed by mechanically abrading surrounding portions of an electrostatic chuck pedestal during manufacturing. For example, the SCAs 104A-104F may be formed by blasting a surface of the electrostatic chuck pedestal with abrasive particles. Portions of the electrostatic chuck pedestal are masked during the abrasion process. The masked portions of the electrostatic chuck pedestal are not abraded, and form the SCAs 104A-104F. In other examples, laser machining may be used to create the SCAs 104A-104F.

Each of the one or more SCAs 104A-104F is elevated above the substrate-facing surface 102 by a height 106. The height 106 is a distance between an apex of the SCAs 104A-104F and a surrounding substrate-facing surface. In some examples, the height 106 is in a range of 0.5-50.0 thousandths of an inch. In other examples, the height 106 may comprise a value that is outside of this range. The height 106 establishes a gap distance between the substrate and areas of the substrate-facing surface of the electrostatic chuck pedestal outside of the SCAs 104A-104F. The gap distance affects a chucking force between the electrostatic chuck pedestal 100 and a substrate.

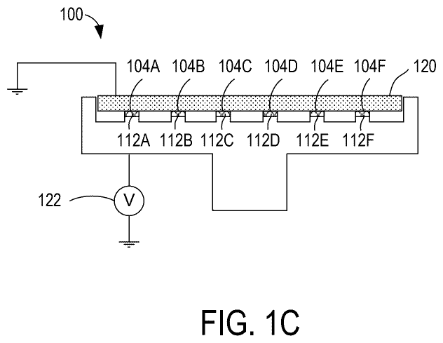

FIG. 2 shows a top-down schematic view of the electrostatic chuck pedestal 100. In this example, each SCA feature 104A-104F comprises a width 107. In some examples, the width 107 is in a range of 0.1-40 thousandths of an inch. In other examples, the width 107 may comprise a value outside of this range. The dimensions of the SCAs 104A-F and SCAs in other FIGS. are exaggerated for clarity.

In some examples, the SCAs 104A-104F cumulatively comprise 0.1-10% of an area of the substrate-facing surface 102. In some more specific examples, the SCAs 104A-104F cumulatively comprise 2-4% of the area of the substrate-facing surface 102. The area of the one or more SCAs 104A-104F affects capacitance and resistance in a current path between the electrostatic chuck pedestal and the substrate. In other examples, the area of the SCAs may comprise a value outside of this range.

Referring again to FIGS. 1A-1B, the tool 101 further comprises a laser 108. The laser 108 is configured to selectively apply a laser beam 110 to the one or more SCAs 104A-104F of the electrostatic chuck pedestal 100 in the presence of oxygen. This results in formation of microstructurally modified layers in the form of oxide layers 112A-112F on each of the one or more SCAs 104A-104F, respectively, as shown in FIG. 1B. As discussed below, a locus of the laser beam 110 may be moved to selectively apply the laser beam 110 to different locations on the substrate substrate-facing surface 102, such as to different SCAs of the SCAs 104A-104F. In some examples, laser beam 110 may be applied under air. In other examples, one or more gas source(s) may be used to control an atmosphere within chamber 103. In such examples, the one or more gas source(s) may comprise any suitable oxygen-containing gas. Examples include molecular oxygen (O₂), ozone (O₃), and nitrous oxide (N₂O). Other gases that may be supplied to chamber 103 comprise inert gases such as molecular nitrogen (N₂) and/or one or more noble gases such as argon (Ar), helium (He), neon (Ne), krypton (Kr), or xenon (Xe). In yet other examples, the laser beam 110 may be applied in a vacuum.

Any suitable type of laser 108 that provides sufficient energy to oxidize the electrostatic chuck material in the presence of oxygen may be used. Examples of suitable lasers include, but are not limited to, a neodymium-doped yttrium aluminum garnet (NdYAG) laser, a flash lamp pumped laser, or a fiber laser. The laser exposure in the presence of oxygen results in the formation of the oxide layer on the selected portions of the substrate-facing surface 102 that are laser treated using the laser beam 110.

The tool 101 further comprises a controller 112 operatively coupled to laser 108. Controller 112 further may be operatively coupled to any other suitable component of tool 101, including flow control hardware for gas source(s) 111. The controller 112 comprises a computing system that controls various controllable components of the tool 101. For example, the controller 112 may control the location of the locus 168 of the laser beam 110 and one or more other characteristics of the laser beam. In this manner, the controller 112 may control formation of the oxide layer.

In some examples, a locus of the laser beam 110 may be moved between selected locations on the electrostatic chuck pedestal 100 using optical devices. Examples of optical devices that can be used to direct the laser beam 110 include one or more scanning mirrors and/or one or more scanning prisms. In other examples, the locus of the laser beam 110 may be moved by moving the laser 108. In further examples, the electrostatic chuck pedestal 100 may be moved during the laser treatment to reposition the laser 108 on different selected surfaces.

Controllably applying the laser beam to selected areas of the substrate-facing surface 102 allows the properties of the electrostatic chuck pedestal to be modified in the selected areas. This can reduce part-to-part variation in surface morphology and composition between electrostatic chuck pedestals. For example, sintering processes used in manufacturing a ceramic AlN pedestal may result in the formation of relatively larger grains of AlN. AlN has a hexagonal wurtzite crystal structure with lattice constants of a=0.312 nm and c=0.498 nm. In contrast, Al₂O₃, which is an example of an oxide that can be formed by the laser treatment, has a trigonal crystal structure with lattice constants of a=0.478 nm and c=1.30 nm. Due to these differences, AlN may not provide an effective template for Al₂O₃ growth. This may allow an oxide layer to form smaller grains than the grains of the AlN pedestal, or even grow in amorphous form. The resulting smaller grains or amorphous structure may help reduce the part-to-part variation. As one example, leakage current between an AlN electrostatic chuck pedestal and a silicon substrate may vary by 100% or more across a population of electrostatic chuck pedestals due to as-manufactured part-to-part variation. Formation of an oxide layer of a controlled thickness on electrostatic chuck pedestals may help to reduce such variation. This may help to achieve more consistent performance across a population of pedestals. The resulting smaller grains or amorphous structure of the oxide layer also may help to reduce a rate of pedestal wear. This is because the removal of a relatively smaller grain during a cleaning process may form a relatively smaller void.

Selectively applying the laser beam 110 may additionally or alternatively comprise controlling one or more characteristics of the laser beam other than location. Some examples of characteristics of the laser beam that can be selectively controlled include one or more of a power of the laser beam, a timing and duration of a laser pulse, a laser beam diameter, or a laser beam focus. Controlling such characteristics of the laser beam enables the oxide layer to be formed with controllable depth, shape, and/or composition.

As mentioned above, in some examples, the electrostatic chuck pedestal comprises AlN. In such examples, the oxide layer comprises one or more of Al₂O₃ or aluminum oxynitride ((AlN)ₓ·(Al₂O₃)₁₋ₓ,). The Al₂O₃ and/or (AlN) x′ (Al₂O₃)₁₋ₓ may increase the resistance of the SCAs 104A-104F. The Al₂O₃ and/or (AlN)ₓ·(Al₂O₃)₁₋ₓ also may reduce the capacitance between the electrostatic chuck pedestal 100 and a substrate. This may help to reduce an electrical power used for substrate clamping. FIG. 1C illustrates a substrate 120 clamped to electrostatic chuck pedestal 100 by application of a voltage from a voltage source 122. The applied voltage causes current to flow between substrate 120 and SCAs 104A-104F. The current flow creates an electrostatic attraction based upon the above-described J-R mechanism. Reducing the clamping current may help prevent or reduce a rate of damage to the electrostatic chuck pedestal from ionic current flow during use. Furthermore, reducing the clamping current may enable the laser-treated electrostatic chuck pedestal to achieve the same clamping force with less power than an untreated pedestal.

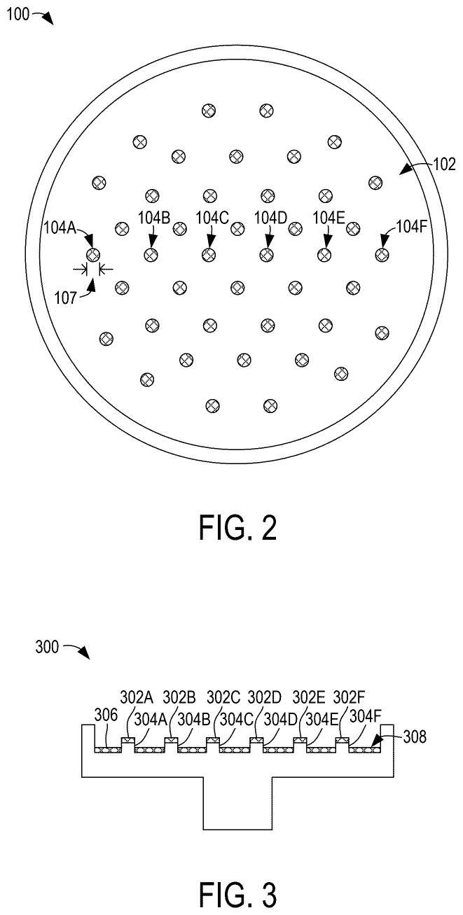

As mentioned above, in some examples, the laser beam 110 may be used to form SCAs via laser ablation of surrounding areas of the substrate-facing surface 102. Forming SCAs by laser machining instead of abrasion can result in the formation of an oxide layer on portions of substrate-facing surface 102 other than the SCAs. This can make the portions of a substrate-facing surface other than the SCAs more damage-resistant. Further, where SCAs are formed from abrasive blasting, the laser beam 110 can be applied to at least a portion of a substrate-facing surface of an electrostatic chuck pedestal 100 outside of the one or more SCAs after formation of the SCAs. FIG. 3 illustrates an example electrostatic chuck pedestal 300 comprising oxide layers 302A-302F on SCAs 304A-304F. Electrostatic chuck pedestal 300 also comprises an oxide layer 306 on regions of substrate-facing surface 308 other than the SCAs 304A-F. In other examples, the oxide layer may be formed on regions of the substrate-facing surface 102 outside of the SCAs 302A-302F, and not the one or more SCAs 304A-304F.

In some examples, the oxide layer can be formed in such a manner as to incorporate a dopant. The dopant may be incorporated into the oxide layer by selectively applying a laser beam to at least a portion of the electrostatic chuck pedestal in the presence of the dopant. The dopant may be used to modify one or more physical and/or chemical properties of the electrostatic chuck pedestal.

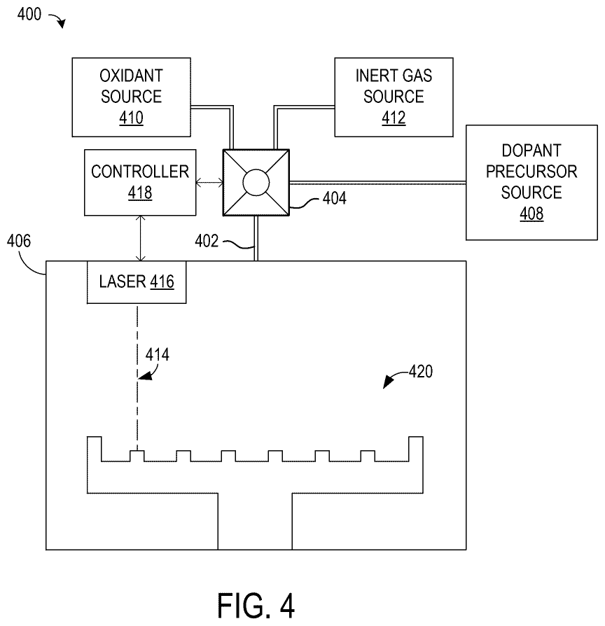

In some examples, a dopant can be introduced by using a gas-phase dopant precursor. FIG. 4 shows an example laser machine 400 comprising one or more processing gas inlets for introducing processing gases into the processing chamber. One example processing gas inlet is shown as processing gas inlet 402. The processing gas inlet 402 is configured to admit a flow of one or more processing gases. The laser machine 400 further comprises flow control hardware 404 for controlling the introduction of processing gases into processing chamber 406. Flow control hardware is connected to a dopant precursor source 408, an oxidantsource 410, and an inert gas source 412. One or more additional gas sources may be added to introduce additional gases into the processing chamber 406. Examples include a hydrogen gas source to control an oxidative environment within the chamber 406.

The dopant-containing precursor is provided in a gas phase. In this manner, the dopant-containing precursor forms at least a portion of an atmosphere in which a laser beam 414 from a laser 416 is applied as a laser treatment. The dopant in the atmosphere may be incorporated into the oxide layer of the electrostatic chuck pedestal as the oxide layer is formed by the laser treatment. The laser treatment can be performed at atmospheric pressure, or at other pressures in other examples. For example, the laser treatment can be performed at less than atmospheric pressure.

The dopant precursor source 408 comprises any suitable dopant-containing precursor. In some examples, the dopant precursor source 408 comprises a silane or a polysilane ((H₃Si—(SiH₂)ₙ—SiH₃), where n≥1). In other examples, the dopant precursor source 408 additionally or alternatively comprises a siloxane. Example siloxanes include octamethylcyclotetrasiloxane (OMCTS), octamethoxydodecasiloxane (OMODDS), tetramethylcyclotetrasiloxane (TMCTS), triethoxysiloxane (TRIES), and tetraoxymethylcyclotetrasiloxane (TOMCTS). Other examples of suitable dopant-containing precursors include, but are not limited to, elemental silicon, silicon nitride, silicon oxide, silicon oxynitride, pure elements (such as a metal), or compounds such as metal oxides, nitrides, nitrates, carbonates, oxalates, and metal-organic compounds such as alkoxides and salts of carboxylic acids.

Oxidant source 410 may comprise any suitable oxidant. Examples include oxygen (O₂), ozone (O₃), water (e.g., liquid or vapor), and nitrous oxide N₂O. In some examples, oxidant source 410 may comprise an air source.

In some examples, a dopant may be provided in a different laser treatment step than an oxide-forming laser treatment step. For example, a carbon-containing precursor may be applied in a laser treatment step either before or after a separate oxide-forming treatment step. This may help to prevent forming volatile oxidized carbon species such as carbon dioxide during laser treatment.

Inert gas source 412 comprises any suitable inert gas. Examples of inert gases include one or more of N₂, He, Ne, Ar, Kr, or Xe. N₂ may be introduced with an oxidant to form a nitrogen-enriched atmosphere. Applying the laser beam 414 in a nitrogen-enriched atmosphere may result in a more nitride-rich oxide layer relative to an oxide layer formed in air.

Controller 418 is further coupled to flow control hardware 404. In this manner, the controller 418 is configured to operate flow control hardware 404 to flow a selected chemical or mixture of chemicals at a selected rate into processing chamber 406. In this manner, the controller 418 may control a composition of the oxide layer formed on electrostatic chuck pedestal 420.

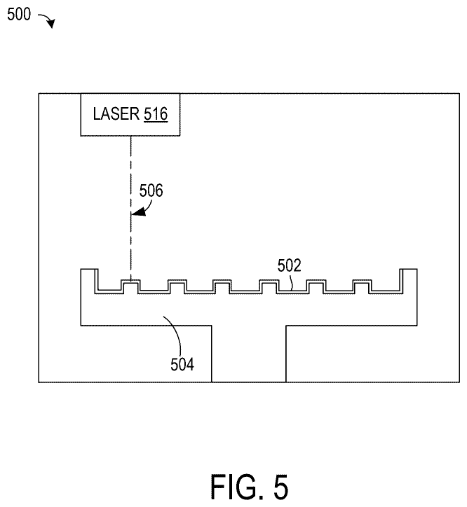

In the example of FIG. 4, laser machine 400 is configured to introduce a dopant precursor in a gas phase. FIG. 5 shows another example laser machine 500 configured to implement a doping process in which a dopant precursor is provided as a layer of material 502 on electrostatic chuck pedestal 504 prior to applying laser beam 506 using a laser 516. For example, a powder (e.g., a dry powder or a powder in liquid suspension) comprising the dopant precursor can be applied to the electrostatic chuck pedestal 504. A dopant precursor also may be applied as a foil. A solid film comprising the dopant can also be applied using methods such as chemical vapor deposition (CVD), atomic layer deposition (ALD), sputtering, evaporation, or liquid phase application followed by solvent evaporation. The dopant may be incorporated into the oxide layer of the electrostatic chuck pedestal from the dopant precursor as the oxide layer is formed by the laser treatment. Excess dopant precursor can be removed from the pedestal after laser treatment using a suitable cleaning method, such as an acid cleaning or plasma cleaning. Yet another example of incorporating a dopant comprises ion implantation.

Referring again to FIG. 1B, the oxide layer 112F comprises a thickness 124 of greater than or equal to 100 nm. In more specific examples, the oxide layer comprises a thickness in a range of 100 nm-2000 nm. In further examples, the oxide layer comprises a thickness in the range of 900-1100 nm. In yet other examples, the oxide layer may comprise a thickness outside of these ranges. In any of these examples, the thickness 124 of the oxide layer is greater than that of a native oxide layer that forms on an AlN pedestal due to exposure to air. Accordingly, and in one potential advantage of the present disclosure, the thickness 124 of the oxide layer may prevent tunneling current and thereby increase resistance between the electrostatic chuck pedestal 100 and the substrate 120 compared to a native oxide layer. On the other hand, an oxide layer formed by laser treatment also may be configured to be sufficiently thin such that thermal expansion during operation of the electrostatic chuck pedestal does not exceed a fracture strength of the oxide layer.

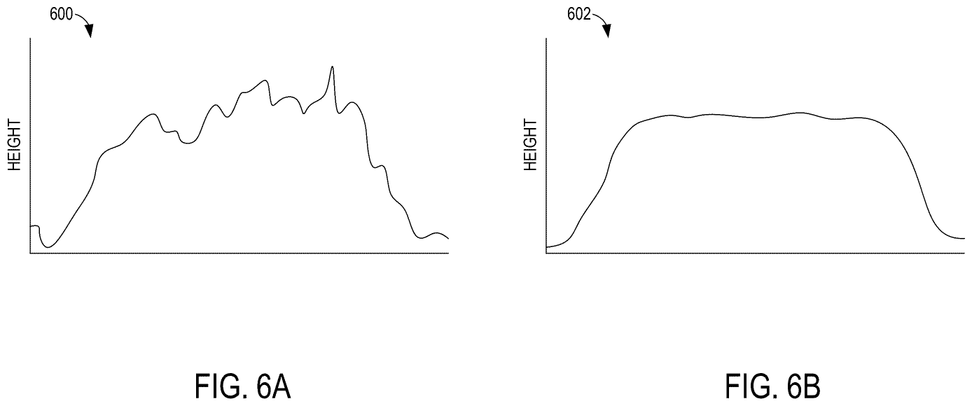

With reference now to FIGS. 6A-6B, a laser treatment also may be used to refurbish a degraded electrostatic chuck pedestal. FIG. 6A shows a plot of a surface relief profile 600 for an example of a SCA on a degraded electrostatic chuck pedestal. Surface relief profile 600 represents a plot obtained using a laser profiler. As mentioned above, operating conditions such as cleaning and relatively higher chucking currents may degrade SCAs of an electrostatic chuck pedestal over time. This may result in irregular surfaces that reduce a magnitude of chucking force relative to a newly fabricated electrostatic chuck pedestal. Thus, laser ablation can be used to selectively remove material from the degraded electrostatic chuck pedestal. This results in a more uniform surface relative to the original surface relief profile 600, as indicated in the example surface relief profile 602 of FIG. 6B. Advantageously, the laser ablation may remove less material than machining. This may result in a refurbished electrostatic chuck pedestal that is similar in height to the pristine electrostatic chuck pedestal. This may enable an electrostatic chuck pedestal to undergo multiple cycles of use and refurbishment. The laser ablation, when performed in the presence of oxygen, also may form a new oxide layer or thicken an existing degraded oxide layer.

An oxide layer formed on a substrate-facing surface of an electrostatic chuck as described herein may be more resistant to wear than a bulk material of an electrostatic chuck pedestal. As mentioned above, in the example of a pedestal comprising an aluminum nitride substrate-facing surface, the aluminum oxide layer has a different unit cell structure than the aluminum nitride bulk material. The aluminum oxide also has dissimilar lattice constants compared to the aluminum nitride. Thus, the bulk material may not serve as a template for growth of the oxide layer. This may help to avoid the aluminum oxide forming a similar grain structure to the bulk aluminum nitride. Instead, the oxide layer may have an amorphous structure or smaller-grained crystals than the bulk material. As a result, the oxide layer may be more resistant to localized attack (e.g., in a fluorine-based plasma) than the bulk material.

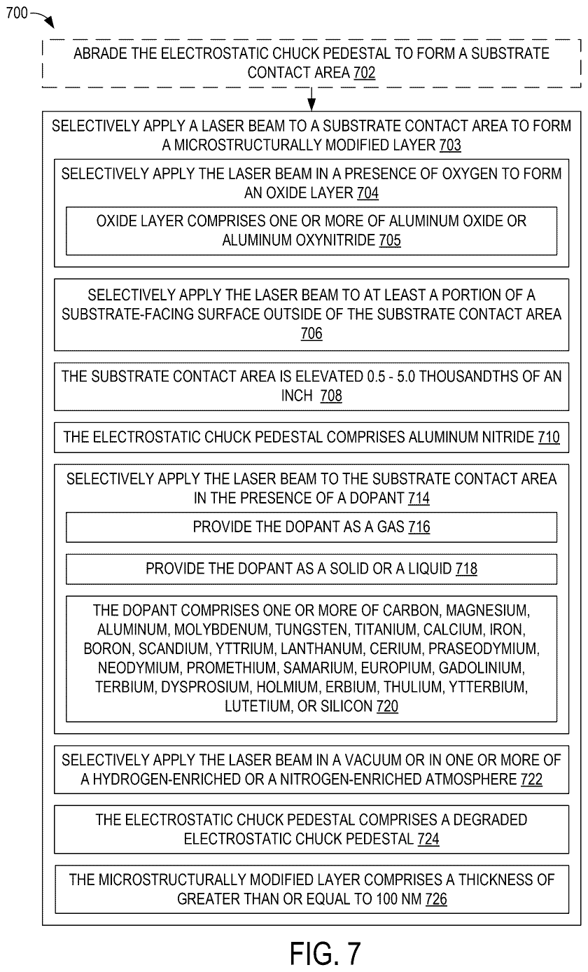

FIG. 7 shows a flow diagram depicting an example method 700 for laser treating an electrostatic chuck pedestal. The following description of the method 700 is provided with reference to the components described above and shown in FIGS. 1A-6 and 9. It will be appreciated that the method 700 also may be performed in other contexts.

In some examples, the method 700 comprises, at 702, prior to selectively applying the laser beam, abrading the electrostatic chuck pedestal to form a SCA. For example, the electrostatic chuck pedestal 100 of FIGS. 1A-1C may be machined or blasted with an abrasive to form the SCAs 104A-104F prior to laser treatment with the laser beam 110. In other examples, the SCAs 104A-104F may be formed using laser ablation. The SCAs 104A-104F are configured to secure the substrate relative to the electrostatic chuck pedestal 100 by electrostatic force.

The method 700 further comprises, at 703, selectively applying a laser beam to the SCA of the electrostatic chuck pedestal to thereby form a microstructurally modified layer on at least a portion of the SCA. For example, the laser beam 110 of FIGS. 1A-1B is applied to the SCAs 104A-104F of the electrostatic chuck pedestal 100. This results in the formation of the oxide layer 112A-112F on the SCAs 104A-104F. In some examples, the laser beam is applied under air. In other examples, the laser beam is applied under a controlled atmosphere comprising oxygen. The oxygen may be provided as molecular O₂, or another oxygen-containing molecule. Examples of other oxygen-containing molecules include H₂O₂, H₂O, O₃, and N₂O.

In some examples, at 704, the method 700 comprises selectively applying the laser beam to the SCA in a presence of oxygen. In this manner, the microstructurally modified layer includes an oxide layer. For example, the electrostatic chuck pedestal 100 comprises the oxide layers 112A-112F on the SCAs 104A-104F. As indicated at 705, in some examples, the oxide layer comprises one or more of Al₂O₃ or (AlN)ₓ·(Al₂O₃)₁₋ₓ,). For example, the oxide layer 112A-112F of FIGS. 1B-1C may comprise Al₂O₃ and/or (AlN)ₓ·(Al₂O₃)₁₋ₓ,) formed by oxidation of the bulk electrostatic chuck pedestal 100.

In some examples, the method 700 comprises, at 706, selectively applying the laser beam to at least a portion of a substrate-facing surface of the electrostatic chuck pedestal outside of the SCA. For example, a laser beam may be applied to the substrate-facing surface 308 of FIG. 3 between the SCAs 304A-304F. This results in microstructurally modifying the substrate-facing surface 308 between the SCAs 304A-304F. In such examples, the electrostatic chuck with SCAs is obtained prior to applying the laser beam to the areas between the SCAs.

In some examples, as indicated at 708, the SCA is elevated 0.5-50 thousandths of an inch above a substrate-facing surface of the electrostatic chuck pedestal. For example, the height 106 of the SCAs 104A-104F of FIGS. 1A-1C may be in the range of 0.5-50 thousandths of an inch. As described above, this height establishes the gap distance between the substrate and the substrate-facing surface of the electrostatic chuck pedestal.

As indicated at 710, in some examples, the electrostatic chuck pedestal comprises AlN. For example, the electrostatic chuck pedestal 100 of FIGS. 1A-1C may comprise AlN. As described above with reference to step 705, in some examples, forming the oxide layer comprises forming one or more of Al₂O₃ or (AlN) x′ (Al₂O₃)₁₋ₓ,). For example, the oxide layer 112A-112F of FIGS. 1B-1C may comprise Al₂O₃ and/or (AlN) x′ (Al₂O₃)₁₋ₓ,) formed by oxidation of the bulk electrostatic chuck pedestal 100. In this manner, the oxide layer may increase a resistance of the electrostatic chuck pedestal 100. This may reduce a power utilized to obtain a targeted clamping force.

In some examples, the method 700 comprises, at 716, selectively applying the laser beam to the SCA in the presence of a dopant to thereby incorporate the dopant into the microstructurally modified layer. The dopant may modify one or more physical or chemical properties of the oxide layer relative to a pure material. For example, the dopant may modify an electrical conductivity, a dielectric constant, a hardness, a thermal conductivity, a dissipation of electromagnetic oscillation, and/or other physical property or properties to achieve a targeted performance.

In some examples, at 716, the method 700 comprises providing the dopant as a gas that forms at least a portion of an atmosphere in which the laser beam is applied to the SCA. For example, a gas-phase dopant precursor is provided into the processing chamber 406 of FIG. 4 to form the microstructurally modified layer. In other examples, at 718, the method 700 comprises providing the dopant as a solid or a liquid on the SCA. For example, the material 502 of FIG. 5, which comprises a dopant precursor comprising the dopant, may be provided on the electrostatic chuck pedestal 100 prior to applying the laser beam. A solid dopant precursor may be provided by a vapor deposition method as a film, or as a suitable powder. A liquid dopant precursor may be applied as a solution, for example, by dip coating, spin coating, doctor blade, or other suitable coating method. Then, the solvent may be evaporated prior to laser treatment. In this manner, application of the laser beam to form the microstructurally modified layer may also incorporate the dopant into the microstructurally modified layer. In some examples, a dopant precursor may be used in a different laser treatment step than a laser treatment step used to form an oxide. For example, a carbon-containing gas-phase dopant precursor may be introduced in a laser treatment step without oxygen present, either before or after a laser treatment step in the presence of oxygen. Where the dopant precursor comprises a powder, the powder may comprise any suitable compound comprising the dopant. Examples include carbonates, oxides, halides, and elemental forms (e.g. graphite or amorphous carbon for doping with carbon).

In some examples, as indicated at 720, the dopant comprises one or more of carbon, magnesium, aluminum, molybdenum, tungsten, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, lutetium, or silicon. For example, the dopant precursor source 408 of FIG. 4 or the material 502 of FIG. 5 may comprise one or more of carbon, magnesium, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, lutetium, or silicon. Selection of these dopant materials may be used to tailor the performance of the electrostatic chuck pedestal.

Further, in some examples, at 722, the method 700 comprises selectively applying the laser beam to the SCA in a vacuum or in one or more of a hydrogen-enriched or a nitrogen-enriched atmosphere. For example, an oxidative or reductive nature of the atmosphere in which an oxide layer is formed may be enriched with N₂ to adjust the composition of the oxide layer. In this manner, the composition of the atmosphere may be used to control the performance of the electrostatic chuck pedestal.

In some examples, at 724, the electrostatic chuck pedestal comprises a degraded electrostatic chuck pedestal. For example, the electrostatic chuck pedestal 100 of FIGS. 1A-1C may comprise a worn electrostatic chuck pedestal. The worn electrostatic chuck pedestal may have an irregular surface relief profile, such as the surface relief profile 600 of FIG. 6A. Selective laser ablation can refurbish the worn electrostatic chuck pedestal. This enables the refurbished electrostatic chuck pedestal to undergo one or more additional cycles of use.

As indicated at 726, in some examples, the microstructurally modified layer comprises a thickness of greater than or equal to 100 nm. For example, the thickness 124 of the oxide layer of FIGS. 1B-1C may be greater than or equal to 100 nm. This thickness provides suitable insulation between the electrostatic chuck pedestal 100 and the substrate 120. The thickness of the oxide layer may also be selected to prevent damage from thermal expansion during operation.

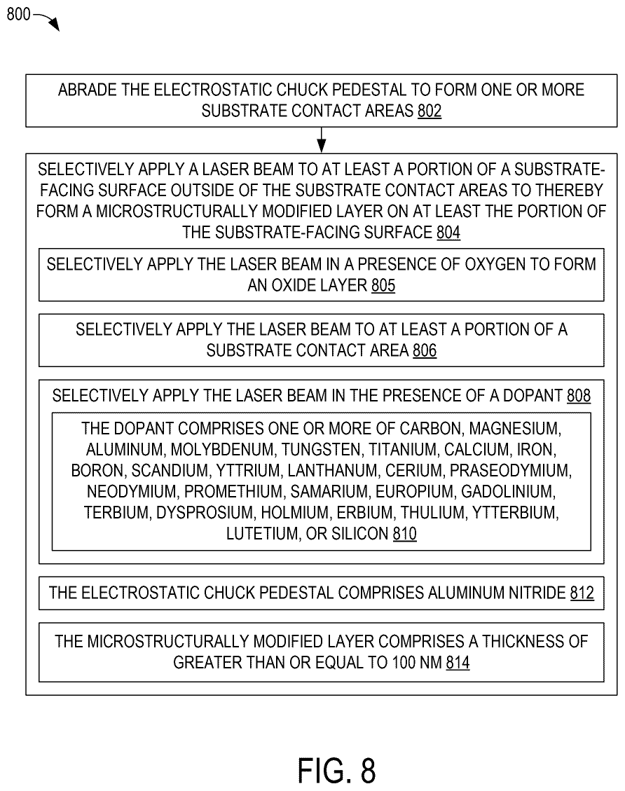

FIG. 8 shows a flow diagram depicting another example of a method 800 for laser treating an electrostatic chuck pedestal. The following description of the method 800 is provided with reference to the components described above and shown in FIGS. 1A-7 and 9. It will be appreciated that the method 800 also may be performed in other contexts using other suitable components.

The method 800 comprises, at 802, prior to selectively applying the laser beam, abrading the electrostatic chuck pedestal to form the one or more SCAs. For example, and as described above, the electrostatic chuck pedestal 100 of FIGS. 1A-1C may be machined or blasted with an abrasive to form the SCAs 104A-104F.

At 804, the method 800 comprises selectively applying a laser beam to at least a portion of a substrate-facing surface of the electrostatic chuck pedestal outside of one or more SCAs of the electrostatic chuck pedestal to thereby form a microstructurally modified layer on at least the portion of the substrate-facing surface. For example, a laser beam may be applied to the substrate-facing surface 308 of FIG. 3 outside of the SCAs 304A-304F. This results in the formation of the oxide layer 306 on the substrate-facing surface 308, as described above with reference to FIG. 3.

At 805, in some examples, selectively applying the laser beam to at least the portion of the substrate-facing surface comprises selectively applying the laser beam in a presence of oxygen. In this manner, the microstructurally modified layer includes an oxide layer. For example, the electrostatic chuck pedestal 300 of FIG. 3 includes the oxide layer 306 on the substrate-facing surface 308 as described above.

In some examples, at 806, the method 800 further comprises selectively applying the laser beam to at least a portion of a SCA of the one or more SCAs. For example, the laser beam 110 of FIGS. 1A-1B is applied to the SCAs 104A-104F. In this manner, the microstructurally modified layer 112A-112F is formed on the SCAs 104A-104F.

At 808, in some examples, the method 800 comprises selectively applying the laser beam in the presence of a dopant to thereby incorporate the dopant into the microstructurally modified layer. For example, the microstructurally modified layer may include a dopant as described above with reference to FIGS. 4-5. Example methods of introducing dopants are described above.

In some examples, as indicated at 810, the dopant comprises one or more of carbon, magnesium, aluminum, molybdenum, tungsten, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, lutetium, or silicon. For example, the dopant precursor source 408 of FIG. 4 or the material 502 of FIG. 5 may comprise one or more of these materials. Selection of these dopant materials may be used to tailor the performance of the electrostatic chuck pedestal.

At 812, in some examples, the electrostatic chuck pedestal comprises aluminum nitride. For example, the electrostatic chuck pedestal 100 of FIGS. 1-3 may comprise aluminum nitride. The aluminum nitride may enable the electrostatic chuck pedestal to secure the substrate via electrostatic attraction. The aluminum nitride may further enable the electrostatic chuck pedestal to withstand conditions associated with operational use and cleaning.

In some examples, at 814, the microstructurally modified layer comprises a thickness of greater than or equal to 100 nm. For example, the thickness 124 of the oxide layer of FIGS. 1-3 may be greater than or equal to 100 nm. This thickness provides suitable insulation between the electrostatic chuck pedestal 100 and the substrate 120. The thickness of the oxide layer further prevents damage due to thermal expansion during operation.

Thus, by treating an electrostatic chuck pedestal using a laser beam as disclosed, an oxide layer may be formed on the electrostatic pedestal that provides tailored electrical properties and/or greater damage resistance compared to an untreated electrostatic chuck pedestal.

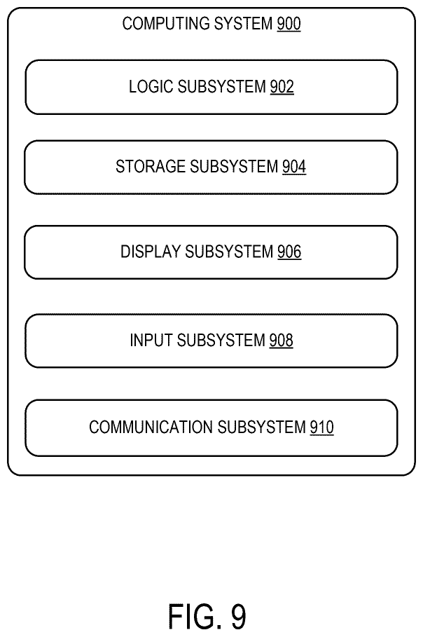

FIG. 9 schematically shows a simplified representation of a computing system 900 configured to provide any to all of the compute functionality described herein. Computing system 900 may take the form of one or more personal computers, server computers, and computers integrated with processing equipment, as examples. Controller 112 is an example of computing system 900.

Computing system 900 includes a logic subsystem 902 and a storage subsystem 904. Computing system 900 may optionally include a display subsystem 906, input subsystem 908, communication subsystem 910, and/or other subsystems not shown in FIG. 9.

Logic subsystem 902 includes one or more physical devices configured to execute instructions. For example, the logic subsystem 902 may be configured to execute instructions that are part of one or more applications, services, programs, routines, libraries, objects, components, data structures, or other logical constructs. Such instructions may be implemented to perform a task, implement a data type, transform the state of one or more components, achieve a technical effect, or otherwise arrive at a desired result.

The logic subsystem 902 may include one or more hardware processors configured to execute software instructions. Additionally, or alternatively, the logic subsystem 902 may include one or more hardware or firmware devices configured to execute hardware or firmware instructions. Processors of the logic subsystem 902 may be single-core or multi-core, and the instructions executed thereon may be configured for sequential, parallel, and/or distributed processing. Individual components of the logic subsystem 902 optionally may be distributed among two or more separate devices, which may be remotely located and/or configured for coordinated processing. Aspects of the logic subsystem 902 may be virtualized and executed by remotely accessible, networked computing devices configured in a cloud-computing configuration.

Storage subsystem 904 includes one or more physical devices configured to temporarily and/or permanently hold computer information such as data and instructions executable by the logic subsystem 902. When the storage subsystem 904 includes two or more devices, the devices may be collocated and/or remotely located. Storage subsystem 904 may include volatile, nonvolatile, dynamic, static, read/write, read-only, random-access, sequential-access, location-addressable, file-addressable, and/or content-addressable devices. Storage subsystem 904 may include removable and/or built-in devices. When the logic subsystem 902 executes instructions, the state of storage subsystem 904 may be transformed—e.g., to hold different data.

Storage subsystem 904 may include removable and/or built-in devices. Storage subsystem 904 may include optical memory (e.g., CD, DVD, HD-DVD, Blu-Ray Disc, etc.), semiconductor memory (e.g., RAM, EPROM, EEPROM, etc.), and/or magnetic memory, among others. Storage subsystem 904 may include volatile, nonvolatile, dynamic, static, read/write, read-only, random-access, sequential-access, location-addressable, file-addressable, and/or content-addressable devices.

Aspects of logic subsystem 902 and storage subsystem 904 may be integrated together into one or more hardware-logic components. Such hardware-logic components may include program- and application-specific integrated circuits (PASIC/ASICs), program- and application-specific standard products (PSSP/ASSPs), system-on-a-chip (SOC), and complex programmable logic devices (CPLDs), for example.

The logic subsystem 902 and the storage subsystem 904 may cooperate to instantiate one or more logic machines. As used herein, the term “machine” is used to collectively refer to the combination of hardware, firmware, software, instructions, and/or any other components cooperating to provide computer functionality. In other words, “machines” are never abstract ideas and always have a tangible form. A machine may be instantiated by a single computing device, or a machine may include two or more sub-components instantiated by two or more different computing devices. In some implementations a machine includes a local component (e.g., software application executed by a computer processor) cooperating with a remote component (e.g., cloud computing service provided by a network of server computers). The software and/or other instructions that give a particular machine its functionality may optionally be saved as one or more unexecuted modules on one or more suitable storage devices.

When included, display subsystem 906 may be used to present a visual representation of data held by storage subsystem 904. This visual representation may take the form of a graphical user interface (GUI). As the herein described methods and processes change the data held by the storage subsystem 904, and thus transform the state of the storage subsystem 904, the state of display subsystem 906 may likewise be transformed to visually represent changes in the underlying data. Display subsystem 906 may include one or more display devices utilizing virtually any type of technology. Such display devices may be combined with the logic subsystem 902 and the storage subsystem 904 in a shared enclosure, or such display devices may be peripheral display devices.

When included, input subsystem 908 may comprise or interface with one or more input devices such as a keyboard, mouse, touch screen. In some embodiments, the input subsystem 908 may comprise or interface with selected natural user input (NUI) componentry. Such componentry may be integrated or peripheral, and the transduction and/or processing of input actions may be handled on- or off-board. Example NUI componentry may include a microphone for speech and/or voice recognition; and an infrared, color, stereoscopic, and/or depth camera for machine vision and/or gesture recognition.

When included, communication subsystem 910 may be configured to communicatively couple computing system 900 with one or more other computing devices. Communication subsystem 910 may include wired and/or wireless communication devices compatible with one or more different communication protocols. As non-limiting examples, the communication subsystem 910 may be configured for communication via a wireless telephone network, or a wired or wireless local- or wide-area network. In some embodiments, the communication subsystem 910 may allow computing system 900 to send and/or receive messages to and/or from other devices via a network such as the Internet.

This disclosure is presented by way of example and with reference to the associated drawing figures. Components, process steps, and other elements that may be substantially the same in one or more of the figures are identified coordinately and are described with minimal repetition. It will be noted, however, that elements identified coordinately may also differ to some degree. It will be further noted that some figures may be schematic and not drawn to scale. The various drawing scales, aspect ratios, and numbers of components shown in the figures may be purposely distorted to make certain features or relationships easier to see.

“And/or” as used herein is defined as the inclusive or V, as specified by the following truth table:

| A | B | A ∨ B |
|---|---|---|
| True | True | True |
| True | False | True |
| False | True | True |
| False | False | False |

The terminology “one or more of A or B” as used herein comprises A, B, or a combination of A and B. The terminology “one or more of A, B, or C” is equivalent to A, B, and/or C. As such, “one or more of A, B, or C” as used herein comprises A individually, B individually, C individually, a combination of A and B, a combination of A and C, a combination of B and C, or a combination of A, B and C.

It will be understood that the configurations and/or approaches described herein are exemplary in nature, and that these specific embodiments or examples are not to be considered in a limiting sense, because numerous variations are possible. The specific routines or methods described herein may represent one or more of any number of strategies. As such, various acts illustrated and/or described may be performed in the sequence illustrated and/or described, in other sequences, in parallel, or omitted. Likewise, the order of the above-described processes may be changed.

The subject matter of the present disclosure includes all novel and non-obvious combinations and sub-combinations of the various processes, systems and configurations, and other features, functions, acts, and/or properties disclosed herein, as well as any and all equivalents thereof.

1. A method for laser treating an electrostatic chuck pedestal, the method comprising:
selectively applying a laser beam to a substrate contact area of the electrostatic chuck pedestal to form a microstructurally modified layer on at least a portion of the substrate contact area.

2. The method of claim 1, wherein selectively applying the laser beam to the substrate contact area comprises selectively applying the laser beam in a presence of oxygen, and wherein the microstructurally modified layer includes an oxide layer.

3. The method of claim 2, wherein the oxide layer comprises one or more of aluminum oxide or aluminum oxynitride.

4. The method of claim 1, further comprising selectively applying the laser beam to at least a portion of a substrate-facing surface of the electrostatic chuck pedestal outside of the substrate contact area.

5. The method of claim 1, wherein the electrostatic chuck pedestal comprises aluminum nitride.

6. The method of claim 1, further comprising selectively applying the laser beam to the substrate contact area in the presence of a dopant to thereby incorporate the dopant into the microstructurally modified layer.

7. The method of claim 6, further comprising providing the dopant as a gas that forms at least a portion of an atmosphere in which the laser beam is applied to the substrate contact area.

8. The method of claim 6, further comprising providing the dopant as a solid or a liquid on the substrate contact area.

9. The method of claim 6, wherein the dopant comprises one or more of carbon, magnesium, aluminum, molybdenum, tungsten, titanium, calcium, iron, boron, scandium, yttrium, lanthanum, cerium, praseodymium, neodymium, promethium, samarium, europium, gadolinium, terbium, dysprosium, holmium, erbium, thulium, ytterbium, lutetium, or silicon.

10. The method of claim 1, further comprising selectively applying the laser beam to the substrate contact area in a vacuum or in one or more of a hydrogen-enriched or a nitrogen-enriched atmosphere.

11. The method of claim 1, wherein the electrostatic chuck pedestal comprises a degraded electrostatic chuck pedestal.

12. The method of claim 1, wherein the microstructurally modified layer comprises a thickness of greater than or equal to 100 nm.

13. A method, comprising:
selectively applying a laser beam to at least a portion of a substrate-facing surface of an electrostatic chuck pedestal outside of one or more substrate contact areas of the substrate-facing surface of the electrostatic chuck pedestal to thereby form a microstructurally modified layer on at least the portion of the substrate-facing surface.

14. The method of claim 13, wherein selectively applying the laser beam to at least the portion of the substrate-facing surface comprises selectively applying the laser beam in a presence of oxygen, and wherein the microstructurally modified layer includes an oxide layer.

15. The method of claim 13, further comprising selectively applying the laser beam to at least a portion of a substrate contact area of the one or more substrate contact areas.

16. The method of claim 13, further comprising selectively applying the laser beam in the presence of a dopant to thereby incorporate the dopant into the microstructurally modified layer.

17. The method of claim 13, wherein the electrostatic chuck pedestal comprises aluminum nitride.

18. The method of claim 13, wherein the microstructurally modified layer comprises a thickness of greater than or equal to 100 nm.

19. An electrostatic chuck pedestal comprising:
a substrate-facing surface comprising a substrate contact area; and
a microstructurally modified layer on at least a portion of the substrate contact area, wherein the microstructurally modified layer comprises a thickness of greater than or equal to 100 nm.

20. The electrostatic chuck pedestal of claim 19, wherein the microstructurally modified layer comprises an oxide layer.
